(19) United States
(12) Patent Application Publication
(10) Pub. No.: US 2023/0238281 A1
(43) Pub. Date: Jul. 27, 2023

(54) METHOD OF MANUFACTURING GALLIUM NITRIDE SUBSTRATE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP); HAMAMATSU PHOTONICS K.K., Hamamatsu-shi (JP); National University Corporation Tokai National Higher Education and Research System, Nagoya-shi (JP)

(72) Inventors: MASATAKE NAGAYA, Nisshin-shi (JP); SHOSUKE NAKABAYASHI, Nisshin-shi (JP); DAISUKE KAWAGUCHI, Hamamatsu-shi (JP); TOSHIKI YUI, Hamamatsu-shi, (JP); CHIAKI SASAOKA, Nagoya-shi (JP); SHOICHI ONDA, Nagoya-shi (JP); JUN KOJIMA, Nagoya-shi (JP)

(21) Appl. No.: 18/153,674

(22) Filed: Jan. 12, 2023

(30) Foreign Application Priority Data
Jan. 26, 2022 (JP) 2022-010196

(51) Int. Cl. H01L 21/784; B23K 26/53; H01L 21/02

(52) U.S. Cl. CPC H01L 21/784; B23K 26/53; H01L 21/02013; B23K 2101/40

(57) ABSTRACT

A method of manufacturing a gallium nitride substrate includes preparation of a gallium nitride wafer, formation of a transformation layer, and formation of the gallium nitride substrate. The gallium nitride has a first main surface and a second main surface on a side opposite from the first main surface. The gallium nitride wafer is made of a hexagonal crystal, and each of the first main surface and the second main surface is a {1-100} m-plane of the hexagonal crystal. The transformation layer is formed along a planar direction of the gallium nitride wafer by emitting a laser beam into the gallium nitride wafer. The gallium nitride substrate is formed from the gallium nitride wafer by dividing the gallium nitride wafer at the transformation layer. In the formation of the transformation layer, the laser beam is emitted to form an irradiation mark for forming the transformation layer.

### CROSS REFERENCE TO RELATED APPLICATION

This application is based on Japanese Patent Application No. 2022-010196 filed on Jan. 26, 2022, the disclosure of which is incorporated herein by reference.

### TECHNICAL FIELD

The present disclosure relates to a method of manufacturing a gallium nitride (GaN) substrate.

### BACKGROUND

A GaN substrate may be manufactured by dividing a GaN wafer. In a method of manufacturing the GaN substrate, a GaN wafer having a first main surface and a second main surface may be prepared, and a laser beam may be emitted from the first main surface or the second main surface into the GaN wafer to form a transformation layer along a planar direction of the GaN wafer. In the method described above, the GaN substrate may be formed by dividing the GaN wafer at the transformation layer as a boundary.

### SUMMARY

The present disclosure describes a method of manufacturing a gallium nitride substrate includes preparation of a gallium nitride wafer, formation of a transformation layer, and formation of the gallium nitride substrate.

### BRIEF DESCRIPTION OF DRAWINGS

Objects, features and advantages of the present disclosure will become more apparent from the following detailed description made with reference to the accompanying drawings. In the drawings:

FIG. 1A is a cross-sectional view of a process of manufacturing a GaN substrate in a first embodiment;

FIG. 1B is a cross-sectional view of a process of manufacturing the GaN substrate following FIG. 1A;

FIG. 1C is a cross-sectional view of a process of manufacturing the GaN substrate following FIG. 1B;

FIG. 1D is a cross-sectional view of a process of manufacturing the GaN substrate following FIG. 1C;

FIG. 1E is a cross-sectional view of a process of manufacturing the GaN substrate following FIG. 1D;

FIG. 1F is a cross-sectional view of a process of manufacturing the GaN substrate following FIG. 1E;

FIG. 2 is a cross-sectional view that illustrates a crystal orientation of a GaN wafer;

FIG. 3 is a schematic diagram that illustrates a path of a laser beam at the time of emitting the laser beam on the GaN wafer;

FIG. 4 is a schematic diagram that illustrates irradiation marks and a wafer transformation layer formed by the laser beam emitted on a region IV in FIG. 3;

FIG. 5 illustrates a relationship among an angle formed with respect to a-axis direction, a total output of the laser beam and the irradiation marks;

FIG. 6A is a schematic diagram that illustrates irradiation marks in a situation where the angle formed between the a-axis direction and the scanning direction is 0 degree;

FIG. 6B is a schematic diagram that illustrates irradiation marks in a situation where the angle formed between the a-axis direction and the scanning direction is 10 degrees;

FIG. 6C is a schematic diagram that illustrates irradiation marks in a situation where the angle formed between the a-axis direction and the scanning direction is 20 degrees;

FIG. 7 is a schematic diagram showing irradiation marks for forming a transformation layer for a wafer in a comparative example;

FIG. 8A is a schematic diagram that illustrates a plane divided in the method in the first embodiment;

FIG. 8B is a schematic diagram that illustrates a plane divided in the method in a comparative example;

FIG. 9A is a cross-sectional view of a process of manufacturing a semiconductor chip including a process of manufacturing a GaN substrate in a second embodiment;

FIG. 9B is a cross-sectional view of a process of manufacturing the semiconductor chip following FIG. 9A;

FIG. 9C is a cross-sectional view of a process of manufacturing the semiconductor chip following FIG. 9B;

FIG. 9D is a cross-sectional view of a process of manufacturing the semiconductor chip following FIG. 9C;

FIG. 9E is a cross-sectional view of a process of manufacturing the semiconductor chip following FIG. 9D;

FIG. 9F is a cross-sectional view illustrating a process of manufacturing the semiconductor chip following FIG. 9E;

FIG. 9G is a cross-sectional view illustrating a process of manufacturing the semiconductor chip following FIG. 9F;

FIG. 9H is a cross-sectional view illustrating a process of manufacturing the semiconductor chip following FIG. 9G;

FIG. 9I is a cross-sectional view illustrating a manufacturing process of the semiconductor chip following FIG. 9H;

FIG. 9J is a cross-sectional view illustrating a manufacturing process of the semiconductor chip following FIG. 9I;

FIG. 9K is a cross-sectional view illustrating a manufacturing process of the semiconductor chip following FIG. 9J;

FIG. 10 is a schematic plan view of the GaN wafer;

FIG. 11A is a schematic view of a structure with formation of the wafer transformation layer and without formation of a chip transformation layer; and

FIG. 11B is a schematic view of a structure with the formation of the wafer transformation layer after the formation of the chip transformation layer.

### DETAILED DESCRIPTION

In a comparative method of manufacturing a GaN substrate by dividing a GaN wafer at a transformation layer as a boundary, respective plane orientations of a first main surface and a second main surface of the GaN wafer may not be particularly defined. The inventors in the present application confirmed that the time for manufacturing the GaN substrate may take longer in a situation where each of the first main surface and the second main surface of the GaN wafer is a generally adopted {0010} c-plane and the transformation layer is formed along the c-plane.

According to an aspect of the present disclosure, a method of manufacturing a gallium nitride substrate includes preparation of a gallium nitride wafer, formation of a transformation layer, and formation of the gallium nitride substrate. The gallium nitride has a first main surface and a second main surface on a side opposite from the first main surface. The gallium nitride wafer is made of a hexagonal crystal, and each of the first main surface and the second main surface is a {1-100} m-plane of the hexagonal crystal. The transformation layer is formed along a planar direction of the gallium nitride wafer by emitting a laser beam into the gallium nitride wafer from the second main surface of the gallium nitride wafer. The gallium nitride substrate is formed from the gallium nitride wafer, by dividing the gallium nitride wafer at the transformation layer as a boundary. In the formation of the transformation layer, the laser beam is emitted to form an irradiation mark for forming the transformation layer in the gallium nitride wafer.

According to the above method, the GaN wafer in which each of the first main surface and the second main surface is the m-plane is prepared, and the laser beam is emitted to form the transformation layer along a planar direction, that is, the m-plane of the GaN wafer. Therefore, it is possible to shorten the time for manufacturing the GaN substrate.

The following describes several embodiments of the present disclosure with reference to the drawings. In the following embodiments, the same or equivalent parts are denoted by the same reference numerals.

### First Embodiment

The following describes a method of manufacturing a GaN substrate 100 in a first embodiment with reference to drawings. The GaN substrate 100 according to the present embodiment may be mounted on a vehicle such as an automobile and applied as a device for driving various electronic devices for the vehicle. In the case of indicating the crystal orientation, a bar (-) should be added over a desired number properly. Since there is restriction on expression based on electronic filing, in the present specification, a bar is attached before a desired number.

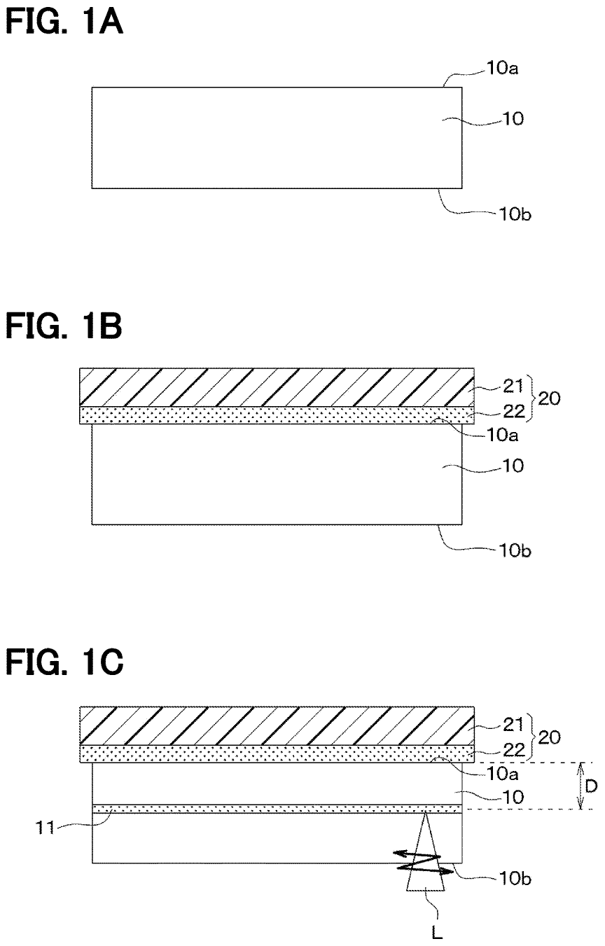

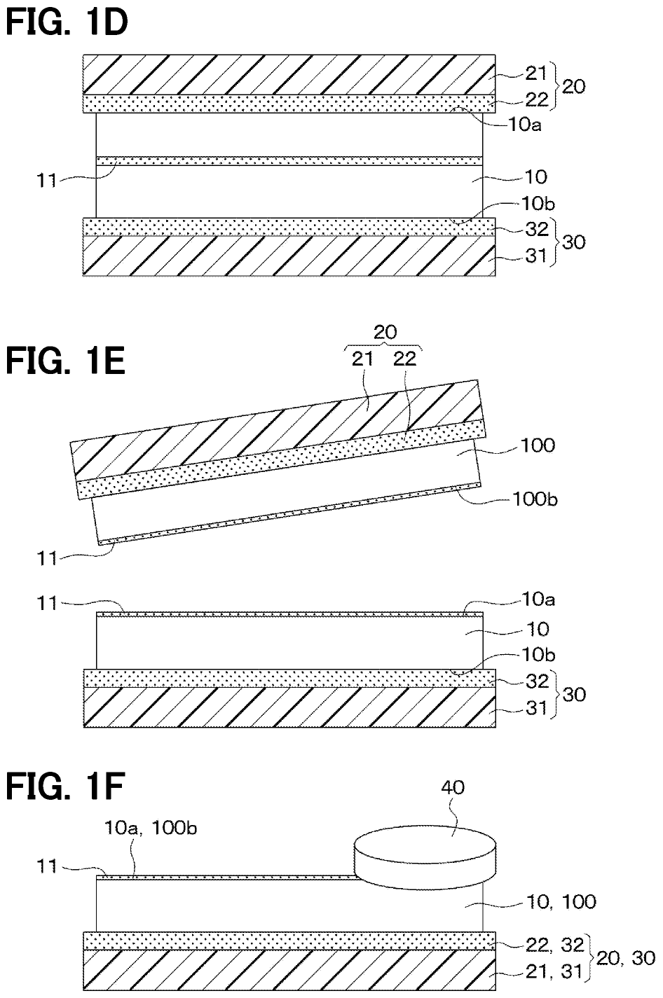

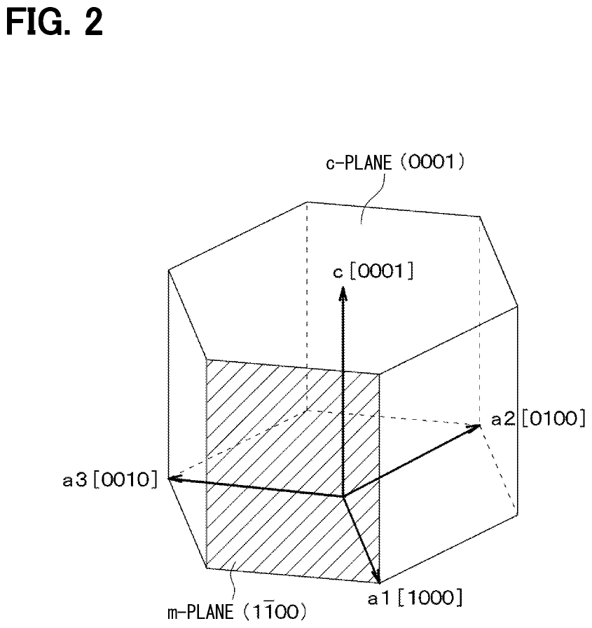

In the present embodiment, as illustrated in FIG. 1A, a GaN wafer 10 is prepared. The GaN wafer 10 includes a first main surface 10a and a second main surface 10b, and is formed in a bulk wafer shape. The GaN wafer 10 according to the present embodiment is a hexagonal single crystal wafer, and has a crystal orientation as shown in FIG. 2. In the GaN wafer 10 according to the present embodiment, each of the first main surface 10a and the second main surface is a {1-100} m-plane, and one of directions parallel to the first main surface 10a and the second main surface 10b is a c-axis direction parallel to a<0001> direction or an a-axis direction. For example, in a situation where each of the first main surface 10a and the second main surface 10b is the (1-100) m-plane, a c-axis direction and a a-axis direction are parallel to the m-plane. In the present embodiment, since the laser beam L is emitted from the second main surface 10b, the second main surface 10b is made of a mirror surface by mirror finishing. Mirror finishing is performed, for example, by polishing using a grinder or polishing such as Chemical Mechanical Polishing (CMP). The m-plane in the present embodiment includes, for example, a slight manufacturing tolerance. For instance, the m-plane also includes a plane with a tilted angle of plus or minus 3 degrees with respect to the m-plane. In other words, each of the first main surface 10a and the second main surface 10b in the present embodiment is a surface formed with the m-plane.

Subsequently, as illustrated in FIG. 1B, a holding member 20 is arranged at the GaN wafer 10 on the first main surface 10a side. As the holding member 20, for example, a dicing tape or the like having a base material 21 and an adhesive 22 is used. The base material 21 is made of a material that does not easily warp during the manufacturing process. For example, the base material 21 is made of glass, a silicon substrate, ceramics, or the like. The adhesive 22 is made of a material whose adhesive strength can be changed. For example, the adhesive 22 is made of an adhesive whose adhesive force changes depending on temperature or light. In this case, the adhesive 22 is made of, for example, an ultraviolet curable resin, wax, double-sided tape, or the like.

Subsequently, as illustrated in FIG. 1C, the laser beam L is emitted from the second main surface 10b of the GaN wafer 10, and a wafer transformation layer 11 along the planar direction, that is, the m-plane of the GaN wafer 10 is formed at a position with a predetermined depth D from the first main surface 10a of the GaN wafer 10. In the present embodiment, in this process, a laser device having, for example, a laser beam source, a spatial optical modulator, a condenser lens and a displaceable stage is prepared. The laser beam source oscillates the laser beam L. The spatial optical modulator modulates the laser beam L output from the laser beam source. The condenser lens condenses the light beam L modulated by the spatial optical modulator. The spatial optical modulator includes, for example, liquid crystal on silicon (LCOS).

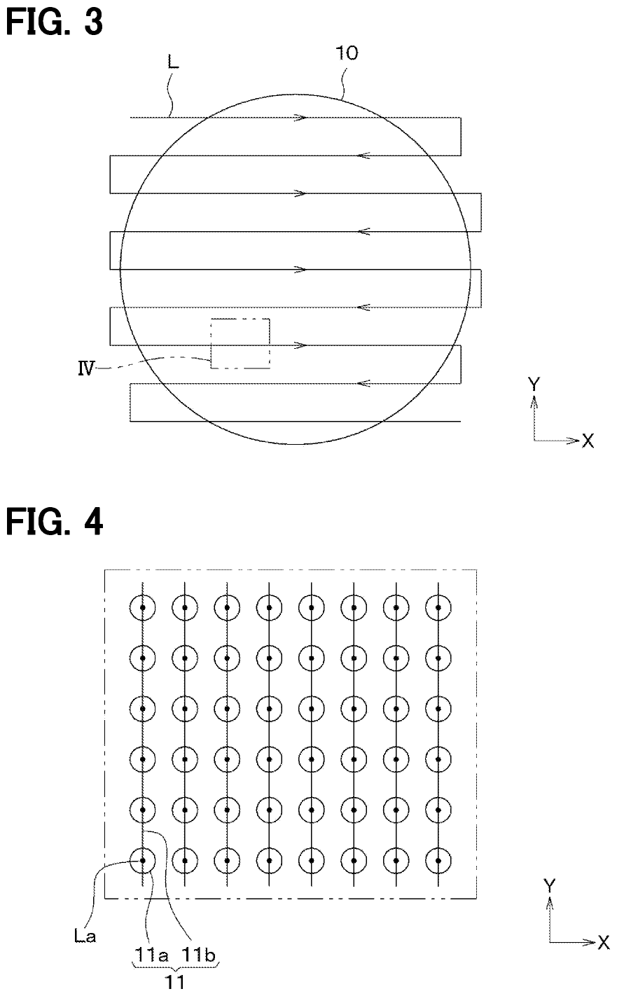

At the time of forming the wafer transformation layer 11, the GaN wafer 10 is placed on the stage, and the position of the stage or the like is adjusted so that the condensing point of the laser beam L is relatively scanned along the planar direction of the GaN wafer 10. In the present embodiment, as illustrated in FIG. 3, in a case where a direction included in the planar direction of the GaN wafer 10 is defined as an X-axis direction; and a direction orthogonal to the X-axis direction is defined as a Y-axis direction, the laser beam L is scanned as described in the following. That is, the laser beam L is scanned in the X-axis direction and shifted in the Y-axis direction, and then again scanned in the X-axis direction. Therefore, it may be said that the scanning direction of the laser beam L is the X-axis direction.

In the present embodiment, when the laser beam L is scanned in the X-axis direction on the GaN wafer 10 while the multiple irradiation marks La are simultaneously formed in the Y-axis direction included in the planar direction of the m-plane. The irradiation mark La is a mark formed by the emission of the laser beam. Although not particularly limited, in the present embodiment, the laser beam L split into six branches while six irradiation marks La are simultaneously formed in the Y-axis direction included in the planar direction of the m-plane. By emitting the laser beam L along the planar direction of such an m-plane while multiple irradiation marks La are simultaneously formed, it is possible to shorten the manufacturing time.

However, in a situation of emitting the laser beam L, the condition is satisfied such that the laser irradiation marks La are formed at a position emitted by the laser beam L. FIG. 4 is a schematic diagram based on a result in a situation where the laser beam L is scanned in a direction parallel to the a-axis direction.

Subsequently, a modified layer 11a is formed around a portion formed with the irradiation marks formed by the emission of the laser beam L. The modified layer 11a is formed by decomposition of gallium and nitrogen through thermal energy. More specifically, by the emission of the laser beam L, the modified layer 11a in which nitrogen is evaporated as a gas and gallium is deposited is formed. In the GaN wafer 10, a crack 11b propagating the planar direction of the m-plane from the modified layer 11a is formed. The wafer transformation layer 11 including the modified layer 11a and the crack 11b is formed inside the GaN wafer 10. The inventors in the present application confirmed that the crack easily propagates in the c-axis direction parallel to the planar direction of the m-plane in a situation where the GaN wafer 10 according to the present embodiment has a hexagonal crystal structure.

FIG. 4 illustrates a schematic diagram in which the distance between adjacent irradiation marks La aligned in the Y-axis direction is adjusted so that the adjacent modified layers 11a aligned in the Y-axis direction is connected through the crack 11b. FIG. 4 is a schematic diagram based on the result in a situation where the laser beam L split into six branches, and based on the result in a situation where a pulse pitch (in other words, the distance between the irradiation marks La in the a-axis direction) is 3 micrometers (μm) and a feed rate is 150 millimeter per second (mm/s).

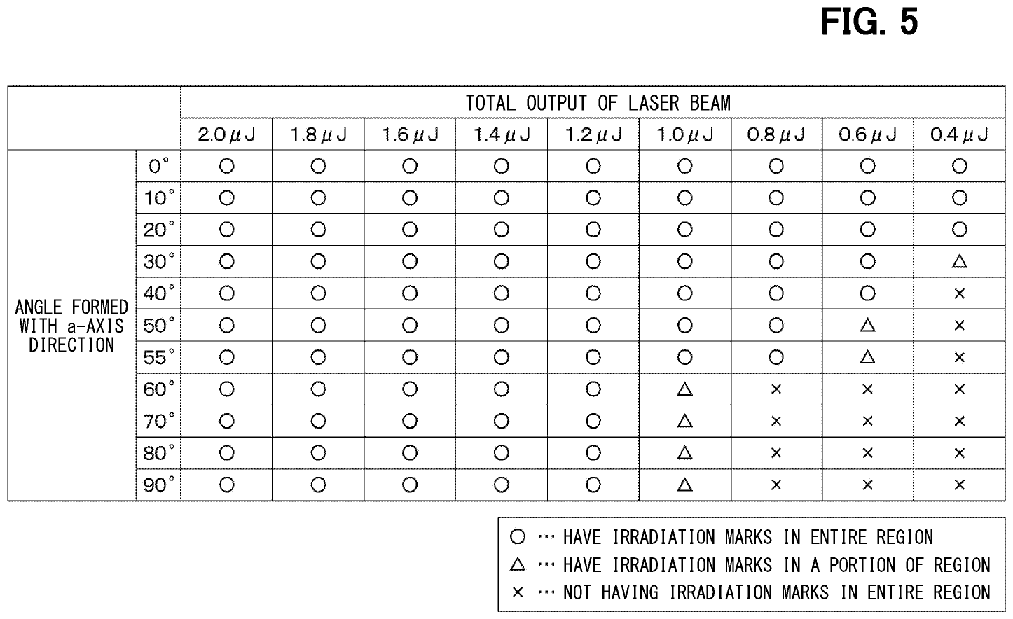

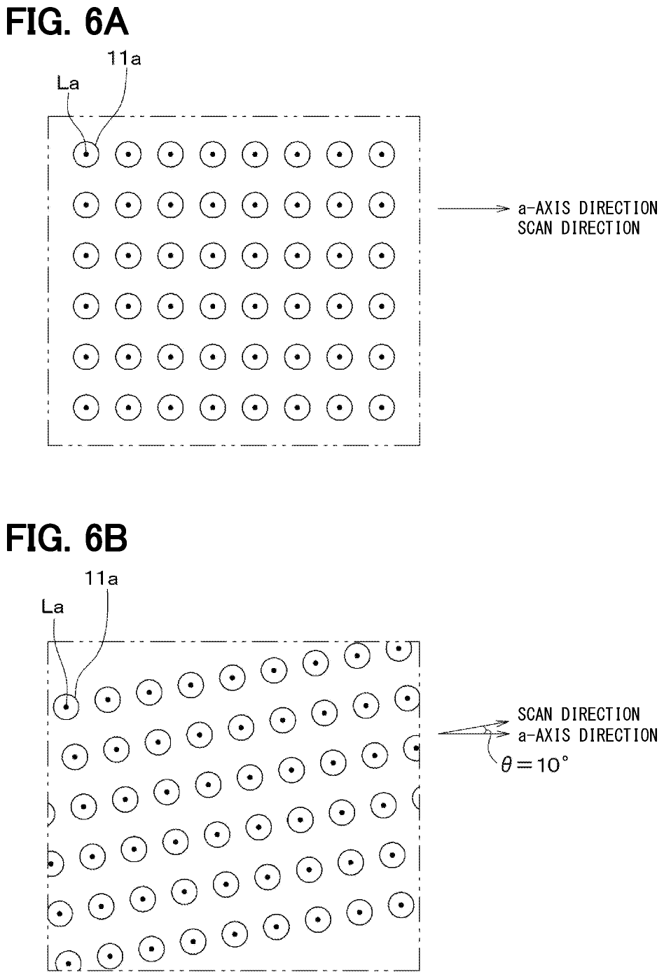

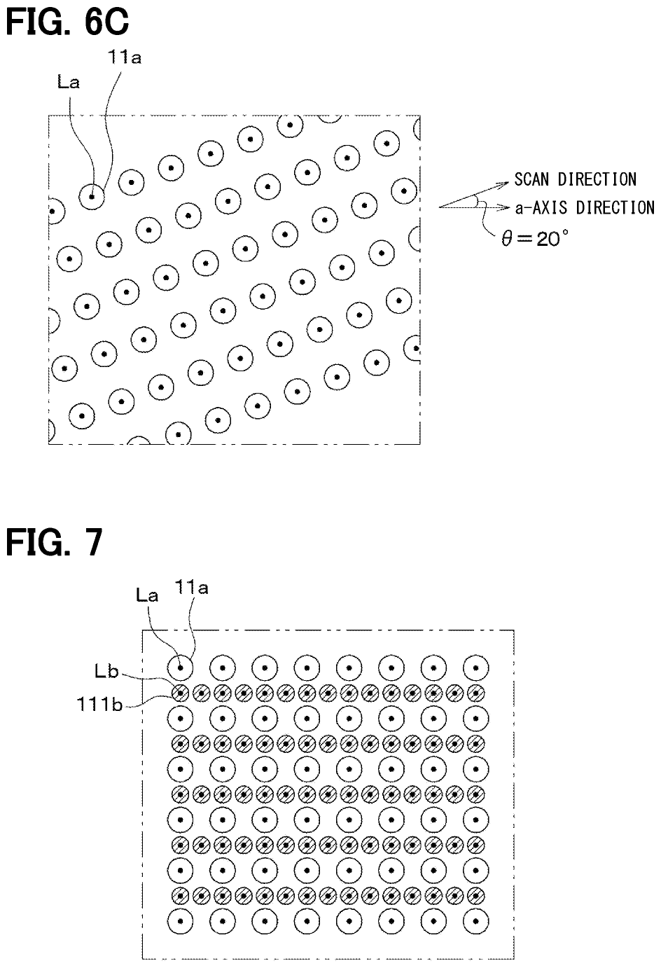

The inventors in the present application acquired the result as illustrated in FIG. 5 related to the irradiation marks La. FIG. 5 illustrates a result related to the angle formed with the a-axis direction In FIG. 5, the angle formed with the a-axis direction refers to an angle θ formed between the scanning direction of the laser L (in other words, the X-axis) and the a-axis direction, for example, the angle θ illustrated in each of FIGS. 6A to 6C. FIG. 6A is a schematic diagram that illustrates the irradiation marks La and the modified layer 11a in a situation where the formed angle is 0 degree. FIG. 6B is a schematic diagram that illustrates the irradiation marks La and the modified layer 11a in a situation where the formed angle is 10 degrees. FIG. 6C is a schematic diagram that illustrates the irradiation marks La and the modified layer 11a in a situation where the formed angle is 20 degrees. However, each of FIGS. 6A to 6C omits the illustration of the crack 11b. In FIG. 5, the total output of the laser beam is the total output of the laser beam L split into several branches. For example, in a situation where the laser beam L is split into six branches as in the present embodiment, it is the total output of the laser beam L split into six branches.

As illustrated in FIG. 5, the inventors in the present application confirmed that the irradiation marks La may not be formed with the total output of 1.0 micro Joule (μJ) or less based on a condition that the angle θ formed between the a-axis direction and the scanning direction is 60 degrees or larger. Additionally, the inventors in the present application confirmed that the irradiation marks La may not be formed with the total output of 0.6 μJ or less based on a condition that the angle formed between the a-axis direction and the scanning direction is 50 degrees or larger. Additionally, the inventors in the present application confirmed that the irradiation marks La may not be formed with the total output of 0.4 μJ or less based on a condition that the angle formed between the a-axis direction and the scanning direction is 30 degrees or larger. The matter of without having irradiation marks La refers to a situation in which the modified layer 11a and the crack 11b are either not formed and a situation in which the wafer transformation layer 11 is not formed even with the emission of the laser beam L.

In the present embodiment, when the laser beam L is emitted, the irradiation marks La are formed at a position irradiated with the laser beam L. In particular, when the laser beam L is scanned, whether or not the formation of the irradiation marks La changes depends on the angle θ formed between the a-axis direction and the scanning direction. The required total output of the laser beam L changes according to the conditions for forming the irradiation marks La including a situation where the angle θ formed between the a-axis direction and the scanning direction is 60 degrees or larger, a situation where the angle θ formed between the a-axis direction and the scanning direction is 50 degrees or larger, and a situation where the angle θ formed between the a-axis direction and the scanning direction is 30 degrees or larger. In other words, under the conditions in which the irradiation marks La are formed, the boundary angles being the respective angles θ formed between the a-axis direction and the scanning direction are 60 degrees, 50 degrees and 30 degrees. In the present embodiment, the angle θ formed between the a-axis direction and the scanning direction is adjusted according to the total output of the laser beam L to form the irradiation marks La while scanning the laser beam L. Specifically, the angle θ formed between the a-axis direction and the scanning direction is adjusted in any one of a range larger than or equal to 60 degrees, a range less than 60 degrees, a range less than 50 degrees and a range less than 30 degree, according to the total output of the laser beam L. In a situation where the angle θ formed between the a-axis direction and the scanning direction is adjusted to be less than 60 degrees, the irradiation marks La may be formed even with lower total output of the laser beam L as compared with a situation in which the angle θ formed between the a-axis direction and the scanning direction is set to 60 degrees or larger. Thus, it is possible to simplify, for example, the structure of the laser device or the adjustment of the laser device.

Subsequently, as illustrated in FIG. 1D, an auxiliary member 30 is arranged at the GaN wafer 10 on the second main surface 10b side. For example, the auxiliary member 30 includes a base material 31 and an adhesive 32 capable of changing the adhesive force, similarly to the holding member 20. In this case, the base material 31 of the auxiliary member 30 is made of, for example, glass, a silicon substrate, ceramics, or the like. Also, the adhesive 32 of the auxiliary member 30 is made of, for example, an ultraviolet curable resin, wax, double-sided tape, or the like.

Then, as illustrated in FIG. 1E, the holding member 20 and the auxiliary member 30 are gripped and a tensile force or the like is applied in the thickness direction of the GaN wafer 10, so that the GaN wafer 10 is divided at the wafer transformation layer 11 as a boundary (that is, the starting point of dividing). Then, the divided portion is configured as the GaN substrate 100. In the present embodiment, a portion supported by the holding member 20 is configured as the GaN substrate 100. The surface of the GaN wafer 10 from which the GaN substrate 100 is divided is referred to as the first main surface 10a of the newly divided GaN wafer 10. The surface of the GaN substrate 100 from which the GaN wafer 10 is divided is referred to as a second surface 100b of the GaN substrate 100.

Subsequently, as illustrated in FIG. 1F, the first main surface 10a and the second main surface 10b are flattened by chemical mechanical polishing (CMP) or the like adopting a grinding device 40. In the present embodiment, the GaN substrate 100 is manufactured from the GaN wafer 10. A variety of semiconductor elements are formed at the GaN substrate 100. The semiconductor device with the GaN substrate 100 is manufactured by dividing the GaN substrate 100 into chip units. The newly divided GaN wafer 10 is used for manufacturing multiple pieces of the GaN substrate 100 by repeating a process after FIG. 1A.

According to the present embodiment, the GaN wafer 10 in which each of the first main surface 10a and the second main surface 10b is the m-plane is prepared, the laser beam L is emitted to form the wafer transformation layer 11 along the planar direction, in other words, the m-plane of the GaN wafer 10. The GaN substrate 100 is manufactured by dividing the GaN wafer 10 at the wafer transformation layer 11 as a starting point. Therefore, it is possible to shorten the time for manufacturing the GaN substrate 100. The following describes a manufacturing method according to a comparative example in which each of the first main surface 10a and the second main surface 10b is a {0001} c-plane, and the wafer transformation layer 11 is formed along the c-plane to manufacture the GaN substrate 100 from the GaN wafer 10. The following describes the comparison between the manufacturing method in the present embodiment and the manufacturing method in the comparative example.

According to the manufacturing method in the present embodiment, the inventors in the present application confirmed that, in a situation where the depth D is set to 200 μm, the feed rate is set to 150 mm/s, the total output of the laser beam L is set to 1.0 μJ, the laser beam L is split into six points to form the wafer transformation layer 11, the required time for dividing the GaN substrate 100 from a two-inch GaN wafer 10 is 15 minutes.

On the other hand, in a situation where the wafer transformation layer 11 is formed along the c-plane as in the manufacturing method according to the comparative example, since the crack 11b is easily formed along the m-plane but is hardly formed along the c-plane, the wafer transformation layer 11 may be preferably formed as illustrated in FIG. 7. An irradiation mark initially formed by the emission of the laser beam L is defined as a main irradiation mark La, and a modified layer formed around the main irradiation mark La is defined as a main modified layer 11a. In this situation, in the manufacturing method according to the comparative example, an additional irradiation mark Lb and an additional modified layer 111b may be formed by the emission of an additional laser beam L at a location including a portion between the adjacent main modified layers 11a. The main irradiation mark La in FIG. 7 may be regarded as equivalent to the irradiation mark in the present embodiment. In the manufacturing method in the comparative example, the time for emitting the laser beam L for forming the additional irradiation mark Lb is required to take an extra time as compared with the manufacturing method in the present embodiment.

The inventors in the present application confirmed that, in a situation where the depth D is set to 200 μm, the feed rate is set to 150 mm/s, the total output of the laser beam L is set to 1.4 μJ, the total output of the laser beam for forming the additional irradiation mark Lb is 0.6 μJ, the required time for dividing the GaN substrate 100 from a two-inch GaN wafer 10 is 300 minutes in the method for manufacturing the GaN substrate 100 in the comparative example. Therefore, according to the method for manufacturing the GaN substrate 100 in the present embodiment, it is possible to sufficiently shorten the manufacturing time.

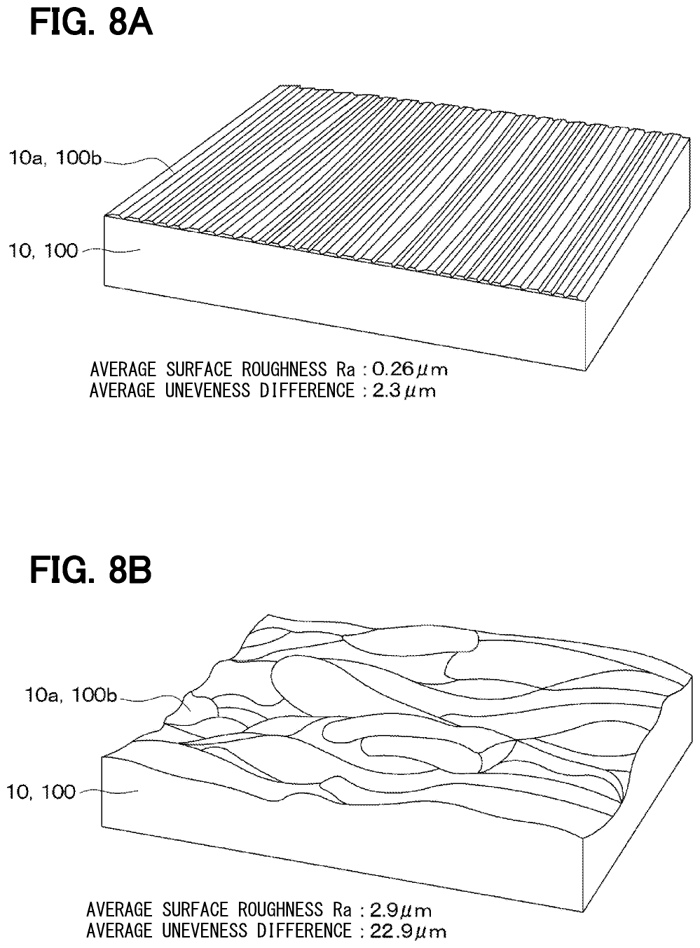

In the present embodiment, the wafer transformation layer 11 along the planar direction, the m-plane of the GaN wafer 10 is formed. The crack 11b forming the wafer transformation layer 11 extends along the m-plane. As illustrated in FIG. 8A, in a situation where the wafer transformation layer 11 is formed along the m-plane as in the present embodiment, it was confirmed that the average surface roughness of each of the divided surfaces 10a, 100b is 0.26 μm, and the maximum unevenness difference is 2.3 μm. As illustrated in FIG. 8B, in a situation where the wafer transformation layer 11 is formed along the m-plane as in the comparative example, it was confirmed that the average surface roughness of each of the divided surfaces 10a, 100b is 2.9 μm, and the maximum unevenness difference is 22.9 μm. The maximum unevenness difference is the difference between the height of the largest protrusion with respect to the reference plane and the depth of the largest recession with respect to the reference plane. According to the manufacturing method in the present embodiment, the surface roughness can be reduced to about one tenth of the surface roughness made in the manufacturing method in the comparative example.

According to the manufacturing method in the present embodiment, at the time of executing the process illustrated in FIG. 1F, it is possible to reduce the amount of GaN to be removed at the time of flattening, and it is possible to reduce the material loss. Since the amount of GaN to be removed at the time of flattening can be reduced, it is possible to shorten the manufacturing time at the time of flattening. FIG. 8B is a schematic view of a surface acquired by forming the main irradiation mark La and the additional irradiation mark Lb to form the wafer transformation layer 11 as in FIG. 7, and dividing the wafer transformation layer 11 as the boundary.

In the present embodiment, the angle θ formed between the scanning direction of the laser beam L and the a-axis direction is adjusted to form the irradiation mark La. Therefore, it is possible to form the wafer transformation layer 11 properly. In a situation where the angle θ formed between the a-axis direction and the scanning direction is adjusted to be less than 60 degrees, the irradiation marks La may be formed even with lower total output of the laser beam L as compared with a situation in which the angle θ formed between the a-axis direction and the scanning direction is set to 60 degrees or larger. Thus, it is possible to simplify, for example, the structure of the laser device or the adjustment of the laser device.

### Second Embodiment

The following describes a second embodiment. The present embodiment is a modification of the structure of the GaN wafer 10 of the first embodiment. The other configurations are the same as those of the first embodiment, and therefore a description of the same configurations will be omitted below.

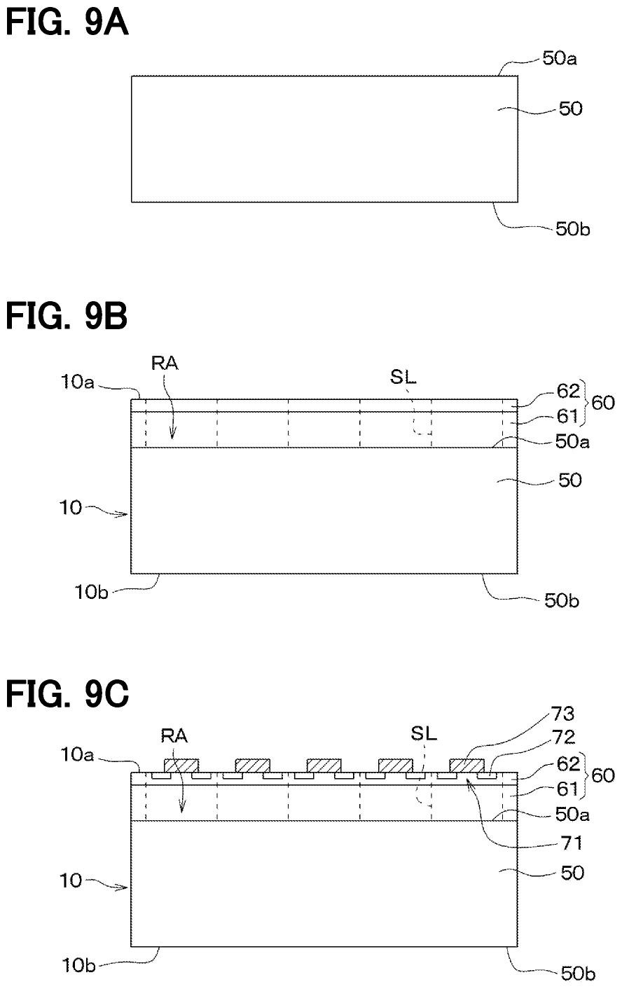

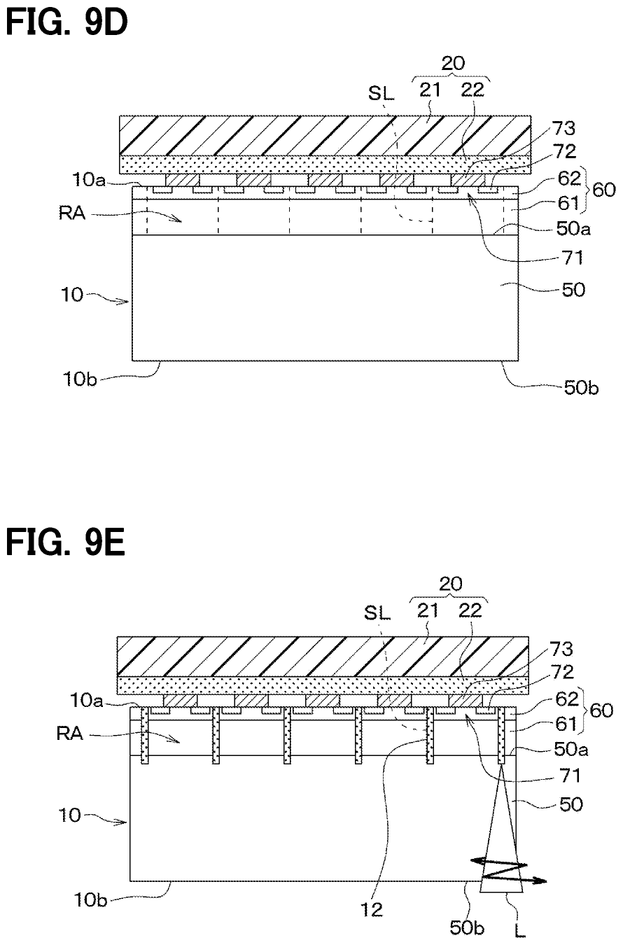

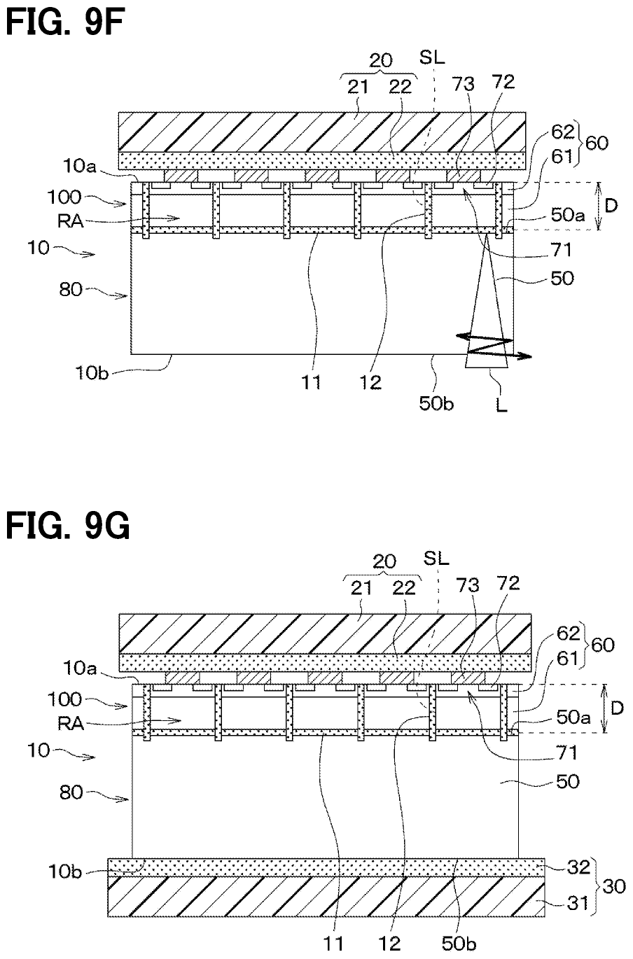

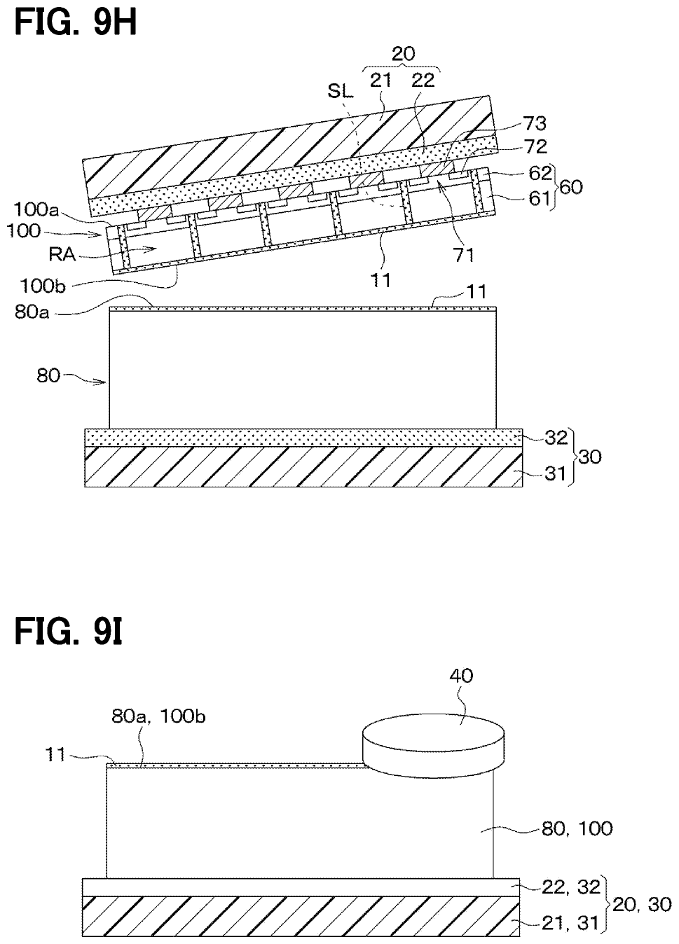

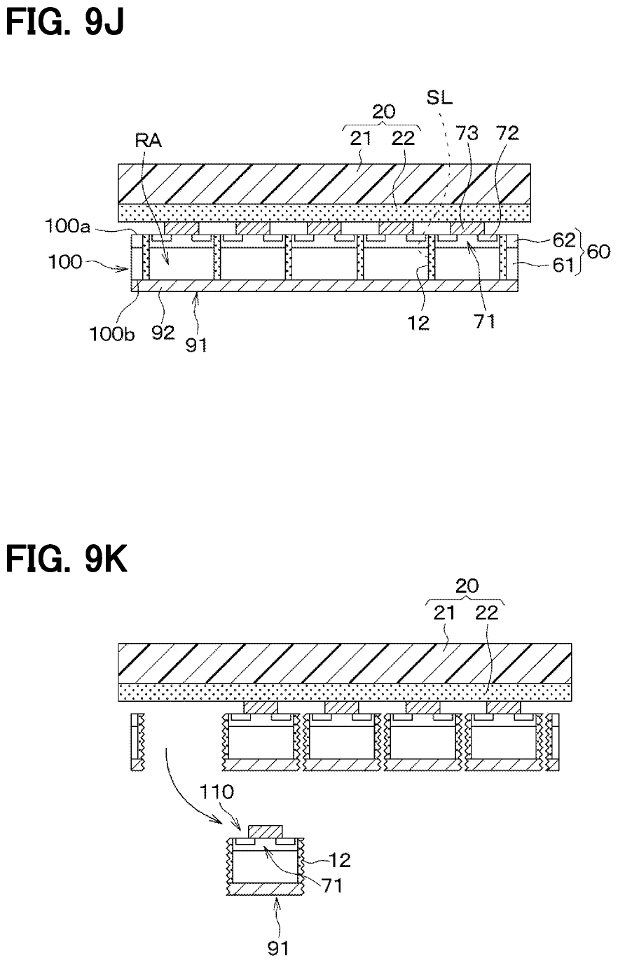

In the present embodiment, as illustrated in FIG. 9A, a base wafer 50 made of GaN is prepared. The base wafer 50 includes a first surface 50a and a second surface 50b, and is formed in a bulk wafer shape. The base wafer 50 is a hexagonal single crystal wafer, and has a crystal orientation as shown in FIG. 2. In the base wafer 50 according to the present embodiment, each of the first surface 50a and the second surface 50b is a {1-100} m-plane, and one of directions parallel to the first main surface 10a and the second main surface 10b is the c-axis direction parallel to the <0001> direction or the a-axis direction. As the base wafer 50 in the present embodiment, a wafer doped with silicon, oxygen, germanium or the like and having an impurity concentration of 5×10¹⁷ cm⁻³ to 5×10¹⁹ cm⁻³ is used. The thickness of the base wafer 50 may be arbitrary. For example, a wafer having a thickness of about 400 μm is prepared.

Next, as shown in FIG. 9B, a GaN wafer 10 having multiple chip formation regions RA partitioned by a separation line SL is prepared by forming an epitaxial film 60 made of GaN with a thickness of about 10 μm to 60 μm on the first surface 50a of the base wafer 50. In the present embodiment, the epitaxial film 60 is formed by depositing an n⁺ type epitaxial layer 61 and an n⁻ type epitaxial layer 62 in order from the GaN wafer 10 side. For example, the n⁺ type epitaxial layer 61 is doped with silicon, oxygen, germanium, or the like and has an impurity concentration of about 5×10¹⁷ cm⁻³ to 1×10¹⁸ cm⁻³. Silicon or the like is doped in the n⁻ type epitaxial layer 62, and the impurity concentration is about 1×10¹⁷ cm⁻³ to 4×10¹⁷ cm⁻³.

The n⁻ type epitaxial layer 62 is a part in which a first surface-side element component 71 such as a diffusion layer 72 is formed. For example, the n⁻ type epitaxial layer 62 has a thickness of about 8 μm to 10 μm. The n⁺ type epitaxial layer 61 is a part for securing the thickness of a semiconductor chip 110. For example, the n⁺ type epitaxial layer 61 has a thickness of about 40 μm to 50 μm. The thickness of the n⁺ type epitaxial layer 61 and the thickness of the n⁻ type epitaxial layer 62 may be arbitrary, for example, here, the n⁺ type epitaxial layer 3a is larger than the n⁻ type epitaxial layer 3b so as to secure the thickness of the semiconductor chip 110.

Hereinafter, a surface of the GaN wafer 10 on the epitaxial film 60 side is referred to as a first main surface 10a of the GaN wafer 10, and a surface of the GaN wafer 10 on the base wafer 50 side is referred to as the second main surface 10b of the GaN wafer 10. The base wafer 50 is made of a hexagonal crystal, the epitaxial film 60 is formed on the first main surface 10a of the base wafer 50, and the second main surface 10b of the GaN wafer 10 is formed with the second surface 50b of the base wafer 50. Therefore, the GaN wafer 10 is made of a hexagonal crystal, and each of the first main surface 10a and the second main surface 10b is the {1-100} m-plane. The chip formation regions RA are formed adjacent to the first main surface 10a of the GaN wafer 10.

Next, as shown in FIG. 9C, a general semiconductor manufacturing process is performed, and a step for forming the first surface side element component 71 of the semiconductor element such as the diffusion layer 72 and a gate electrode 73 and a surface electrode, a wiring pattern and a passivation film not shown is performed in each chip formation region RA. In this case, as the semiconductor element, devices having various configurations are adopted. Examples of the semiconductor element include a power device such as a high electron mobility transistor (HEMT) and an optical semiconductor element such as a light emitting diode. Thereafter, if necessary, a surface protection film made of a resist or the like is formed on the first main surface 10a of the GaN wafer 10.

Subsequently, as illustrated in FIG. 9D, the holding member 20 is arranged at the GaN wafer 10 on the first main surface 10a side, as similar to the process illustrated in FIG. 1B.

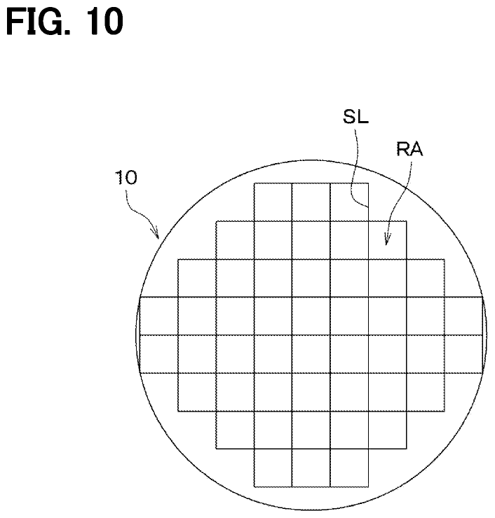

Next, as shown in FIG. 9E, the laser beam L is emitted from the second main surface 10b of the GaN wafer 10, and a chip transformation layer 12 is formed at the separation line SL. In the present embodiment, as shown in FIG. 10, the planar shape of each chip formation region RA surrounded by the separation line SL is formed into a rectangular shape.

In the present embodiment, at the time of executing this process, a laser device identical to the laser device adopted at the time of forming the wafer transformation layer 11 is prepared. The GaN wafer 10 is placed on the stage, and the position of the stage or the like is adjusted so that the condensing point of the laser beam L is relatively scanned along the separation line SL.

As a result, as similar to the wafer transformation layer 11, the chip transformation layer 12 is formed at the separation line SL. The chip transformation layer 12 includes a modified layer in which gallium and nitrogen are decomposed by thermal energy. The chip transformation layer 12 is in a state of having fine pores therein as the nitrogen atom is separated and evaporated.

Further, in the present embodiment, when forming the chip transformation layer 12, the stage or the like is appropriately moved and the laser beam L is applied so that the condensing point moves at two or more locations different in the thickness direction of the GaN wafer 10. In this case, the chip transformation layers 12 are formed at different locations in the thickness direction of the GaN wafer 10. However, the chip transformation layers 12 may be separated from each other or may be connected to each other. Further, when the condensing point is moved at two or more different locations in the thickness direction of the GaN wafer 10, the condensing point is moved from first main surface 10a side to the second main surface 10b side of the GaN wafer 10.

In the chip transformation layer 12, when the wafer transformation layer 11 shown in FIG. 9F is formed, nitrogen generated by forming the wafer transformation layer 11 is emitted to the outside through the pores of the chip transformation layer 12.

Subsequently, as illustrated in FIG. 9F, by executing the process similar to the one illustrated in FIG. 1C, the laser beam L is emitted from the second main surface 10b of the GaN wafer 10, and the wafer transformation layer 11 along the planar direction of the GaN wafer 10 is formed at a position with a predetermined depth D from the first main surface 10a of the GaN wafer 10.

In the present embodiment, the wafer transformation layer 11 is formed so as to intersect the chip transformation layers 12 or extends directly under the chip transformation layers 12. As a result, it is less likely that a large distortion will be applied in each of the chip formation regions RA when the wafer transformation layer 11 is formed.

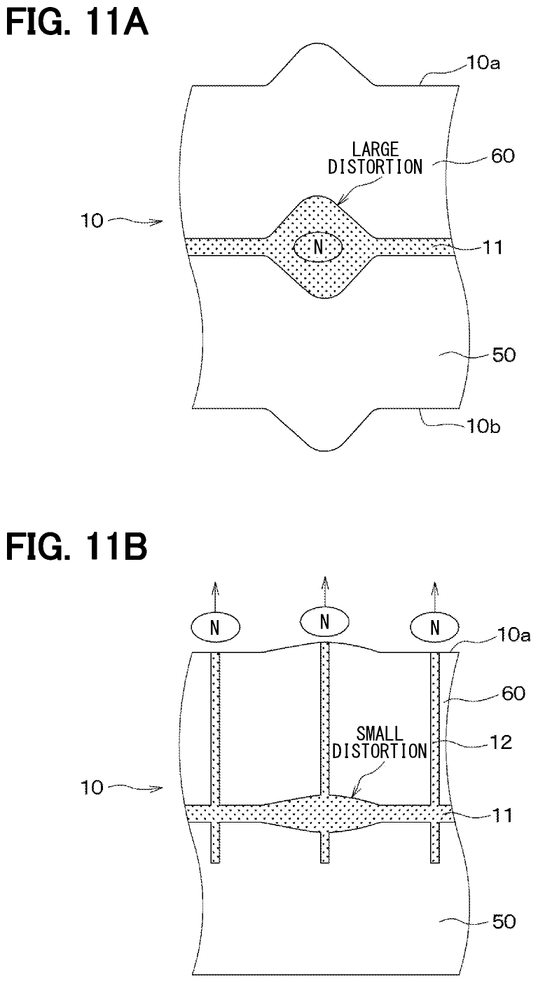

That is, when the chip transformation layer 12 is not formed, as shown in FIG. 11A, the nitrogen (N in FIG. 11A) generated when the wafer transformation layer 11 is formed is difficult to be released to the outside, so that the distortion of the GaN wafer 10 due to the formation of the wafer transformation layer 11 tends to increase. In the present embodiment, on the other hand, the chip transformation layers 12 are formed, and the wafer transformation layer 11 is formed so as to intersect the chip transformation layers 12 or pass directly under the chip transformation layers 12. Therefore, as shown in FIG. 11B, nitrogen (N in FIG. 11B) generated when the wafer transformation layer 11 is formed is easily released to the outside through the pores of the chip transformation layers 12. As such, it is possible to suppress an increase in the distortion of the GaN wafer 10 due to the formation of the wafer transformation layer 11, and it is possible to reduce the distortion applied to each chip formation region RA.

Further, the predetermined depth D to form the wafer transformation layer 11 is set according to the ease of handling of the semiconductor chip 110, the withstand voltage, and the like. For example, the predetermined depth D is about 10 μm to 200 μm. In this case, the position of the wafer transformation layer 11 is changed according to the thickness of the epitaxial film 60. The wafer transformation layer 11 is formed inside of the epitaxial film 60, at the boundary between the epitaxial film 60 and the base wafer 50, or inside of the GaN wafer 10. Note that FIG. 9F shows an example in which the wafer transformation layer 11 is formed at the boundary between the epitaxial film 60 and the GaN wafer 10.

At least a part of the base wafer 50 in the GaN wafer 10 is recycled as a recycle wafer 80. Therefore, the wafer transformation layer 11 may be preferably formed inside the epitaxial film 60 or at the boundary between the epitaxial film 60 and the base wafer 50. In a case where the wafer transformation layer 11 is formed inside the base wafer 50, the wafer transformation layer 11 may be preferably formed adjacent to the first main surface 10a side of the base wafer 50. When the wafer transformation layer 11 is formed inside the epitaxial film 60, the wafer transformation layer 11 is formed inside the n⁺ type epitaxial layer 61 instead of the n⁻ type epitaxial layer 62 constituting the semiconductor element.

Hereinafter, a part of the GaN wafer 10 on the second main surface 10b side from the wafer transformation layer 11 is referred to as the recycle wafer 80, and a part of the GaN wafer 10 on the first main surface 10a side from the wafer transformation layer 11 is referred to as the GaN substrate 100.

Subsequently, as illustrated in FIG. 9G, the auxiliary member 30 is arranged at the GaN wafer 10 on the second main surface 10b side, as similar to the process illustrated in FIG. 1D. Then, as illustrated in FIG. 9H, the holding member 20 and the auxiliary member 30 are gripped and a tensile force or the like is applied in the thickness direction of the GaN wafer 10, so that the GaN wafer 10 is divided into the recycle wafer 80 and the GaN substrate 100 at the wafer transformation layer 11 as a boundary (that is, the starting point of dividing). In other words, the GaN substrate 100 is manufactured from the GaN wafer 10. In the GaN substrate 100, the first surface-side element component 71 is formed at each chip formation region RA.

In the following, the surface of the GaN substrate 100 divided from the recycle wafer 80 is referred to as the second surface 100b of the GaN substrate 100, and the surface on a side opposite from the second surface 100b is referred to as a first surface 100a of the GaN substrate 100. Similarly, the surface of the recycle wafer 80 divided from the GaN substrate 100 is referred to as a first surface 80a of the recycle wafer 80. Since the wafer transformation layer 11 is formed along the planar direction of the GaN wafer 10, the first surface 80a of the divided recycle wafer 80 is the m-plane.

Subsequently, as illustrated in FIG. 9I, CMP is performed with, for example, the grinding device 40 for the first surface 80a of the recycle wafer 80 and the second surface 100b of the GaN substrate 100 to flatten the first surface 80a and the second surface 100b. FIG. 9I omits the illustration of, for example, the first surface-side element component 71 formed at the GaN substrate 100.

The recycle wafer 80 with the flattened first surface 80a is again used as the base wafer 50 to be adopted for the process after FIG. 9A. As a result, the base wafer 50 can be used multiple times to form the semiconductor chips 110.

As shown in FIG. 9J, a general semiconductor manufacturing process is performed. A process for forming a second surface-side element component 91 of a semiconductor element such as a metal film 92 forming a back surface electrode on the second surface 100b of the GaN substrate 100 will be performed. Further, after performing the process of forming the second surface-side element component 91, a heat treatment such as a laser annealing or the like may be performed in order to make an ohmic contact between the metal film 92 and the second main surface 10b of the GaN wafer 10 as necessary.

Subsequently, as shown in FIG. 9K, the holding member 20 is expanded, and the chip formation regions RA are divided at the chip transformation layers 12 as the boundary (that is, the starting point of dividing) to form the semiconductor chips 110. Thereafter, the adhesive force of the adhesive 22 is weakened by a heat treatment or irradiation with light and the first surface 100a side is peeled from the adhesive 22, and the semiconductor chips 110 are picked up. In this way, the semiconductor chips 110 are manufactured. Before dividing the chip formation regions RA, if necessary, a slit or the like may be formed in the metal film 92 at the boundary between the chip formation regions RA so as to easily divide the metal film 92 for each chip formation region RA. In this case, in the process of FIG. 9J, a metal mask covering portions to be divided may be prepared, so that the metal film 92 is not formed on the portions to be divided.

Even though the GaN wafer 10 is formed by stacking the base wafer 50 and the epitaxial film 60, the wafer transformation layer 11 is formed along the m-plane. Thus, it is possible to acquire the effect similar to the one in the first embodiment.

In the present embodiment, the GaN wafer 10 is formed by stacking the base wafer 50 and the epitaxial film 60, and the impurity concentration or the like of the epitaxial film 60 is properly adjusted. Therefore, it is possible to easily modify the characteristics of the manufactured semiconductor chip 110.

In the present embodiment, the recycle wafer 80 is again adopted as the base wafer 50. Therefore, it is not necessary to newly prepare the base wafer 50 every time the semiconductor chips 110 are manufactured, and the base wafer 50 can be effectively used. Therefore, the productivity of the semiconductor chip 110 can be improved.

In the present embodiment, the chip transformation layer 12 is formed before the formation of the wafer transformation layer 11, and, at the time of forming the wafer transformation layer 11, nitrogen generated at the formation of the wafer transformation layer 11 is emitted through the chip transformation layer 12. Therefore, the distortion generated in each chip formation region RA can be reduced, and the occurrence of defects in the semiconductor chip 110 can be suppressed.

### Other Embodiments

Although the present disclosure has been described in accordance with the embodiments, it is understood that the present disclosure is not limited to such embodiments or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

For example, in each of the above embodiments, in a situation where the laser beam is split into several branches and emitted on the GaN wafer 10, the number of branches may be properly modified. The number of branches may be smaller than six, or may be larger than or equal to seven. Additionally, in a situation of emitting the laser beam L on the GaN wafer 10, the laser beam may not have to be split into several branches.

In each of the above embodiments, after the GaN substrate is divided from the GaN wafer 10, the divided second surface 100b of the GaN substrate 100 may not have to be flattened. For example, in a situation where an optical semiconductor element or the like as the semiconductor element is formed at the GaN substrate 100, it is possible to effectively extract the light by remaining roughness with protrusions and recessions.

In the second embodiment, each chip formation region RA may be divided by a dicing blade or the like without forming the chip transformation layer 12. In this situation, by dividing each chip formation region RA before forming the wafer transformation layer 11, it is possible to emit nitrogen generated in the formation of the wafer transformation layer 11. However, in a situation where each chip formation region RA is divided with a dicing blade or the like, each chip formation region RA may be divided after executing the process illustrated in FIG. 9J.

What is claimed is:

1. A method of manufacturing a gallium nitride substrate, the method comprising:
preparing a gallium nitride wafer having a first main surface and a second main surface on a side opposite from the first main surface, the gallium nitride wafer made of a hexagonal crystal, each of the first main surface and the second main surface being a {1-100} m-plane of the hexagonal crystal;
forming a transformation layer along a planar direction of the gallium nitride wafer, by emitting a laser beam into the gallium nitride wafer from the second main surface of the gallium nitride wafer; and
forming the gallium nitride substrate from the gallium nitride wafer, by dividing the gallium nitride wafer at the transformation layer as a boundary,
wherein, in the forming of the transformation layer, the laser beam is emitted to form an irradiation mark for forming the transformation layer in the gallium nitride wafer.

2. The method according to claim 1, further comprising:
flattening at least one of two surfaces of a divided gallium nitride wafer acquired after the dividing of the gallium nitride wafer.

3. The method according to claim 1,
wherein, in the forming of the transformation layer, the laser beam is scanned in a direction as a scanning direction parallel to the second main surface of the gallium nitride wafer to form the irradiation mark while an angle formed between the scanning direction and an a-axis direction of the gallium nitride wafer is set to be smaller than 60 degrees.

4. The method according to claim 1,
wherein, in the forming of the transformation layer, the laser beam is scanned in a direction as a scanning direction parallel to the second main surface of the gallium nitride wafer to form the irradiation mark while an angle formed between the scanning direction and an a-axis direction of the gallium nitride wafer is set to be smaller than 50 degrees.

5. The method according to claim 1,
wherein, in the forming of the transformation layer, the laser beam is scanned in a direction as a scanning direction parallel to the second surface of the gallium nitride wafer to form the irradiation mark while an angle formed between the scanning direction and an a-axis direction of the gallium nitride wafer is set to be smaller than 30 degrees.
